(19) United States
(12) Patent Application Publication
(10) Pub. No.: US 2022/0345112 A1
(43) Pub. Date: Oct. 27, 2022

(54) ACOUSTIC WAVE FILTER AND COMMUNICATION APPARATUS

(71) Applicant: KYOCERA Corporation, Kyoto-shi, Kyoto (JP)

(72) Inventor: Motoki ITO, Ikoma-shi (JP)

(73) Assignee: KYOCERA Corporation, Kyoto-shi, Kyoto (JP)

(21) Appl. No.: 17/762,452

(22) PCT Filed: Sep. 25, 2020
(86) PCT No.: PCT/JP2020/036201

§ 371 Date: Mar. 22, 2022

(30) Foreign Application Priority Data
Sep. 27, 2019 (JP) 2019-177210

(51) Int. Cl. H03H 9/64; H03H 9/05; H03H 9/10

(52) U.S. Cl. CPC H03H 9/6489; H03H 9/6483; H03H 9/059; H03H 9/1085

(57) ABSTRACT

An acoustic wave filter includes a first chip and a second chip electrically connected to the first chip. Each of the chips includes a support substrate, a plurality of acoustic films, a piezoelectric film, and an excitation electrode sequentially stacked on one another. The plurality of acoustic films are sequentially stacked on the support substrate and materials for acoustic films stacked on each other are different from each other.

### TECHNICAL FIELD

The present disclosure relates to an acoustic wave filter that employs acoustic waves and a communication apparatus including the acoustic wave filter.

### BACKGROUND ART

Acoustic wave filters that apply a voltage to an excitation electrode on a piezoelectric body to generate an acoustic wave that propagates through the piezoelectric body are known (e.g., PTL 1). PTL 1 discloses a duplexer in which a first excitation electrode that constitutes a first acoustic wave filter and a second excitation electrode that constitutes a second acoustic wave filter are provided on the same piezoelectric film. The piezoelectric film have different thicknesses at a part corresponding to the first acoustic wave filter and a part corresponding to the second acoustic wave filter. As a result, relative bandwidths of the first and second acoustic wave filters can be easily adjusted.

### CITATION LIST

### Patent Literature

PTL 1: Japanese Unexamined Patent Application Publication No. 2016-072808

### SUMMARY OF INVENTION

An acoustic wave filter according to an aspect of the present disclosure includes a first chip and a second chip electrically connected to the first chip. Each of the first chip and the second chip includes a support substrate and a plurality of acoustic films that are sequentially stacked on the support substrate and whose materials are different between acoustic films stacked on each other, a piezoelectric film located on the plurality of acoustic films, and an excitation electrode located on the piezoelectric film.

A communication apparatus according to another aspect of the present disclosure includes the acoustic wave filter, an antenna electrically connected to the acoustic wave filter, and an integrated circuit device electrically connected to the antenna through the acoustic wave filter.

### BRIEF DESCRIPTION OF DRAWINGS

FIG. 1A and FIG. 1B are perspective diagrams illustrating the appearance of an acoustic wave filter viewed from an upper surface side and a lower surface side, respectively, according to an embodiment.

FIG. 2 is a sectional view taken along line II-II in FIG. 1B.

FIG. 3 is a circuit diagram schematically illustrating an outline of the electrical configuration of the acoustic wave filter illustrated in FIG. 1A.

FIG. 4 is a diagram for describing an example of setting of a resonant frequency for a band-pass filter.

FIG. 5 is a diagram for describing an example of setting of a resonant frequency for a band-elimination filter.

FIG. 6 is a plan view schematically illustrating the configuration of two chips illustrated in FIG. 2.

FIG. 7 is a plan view illustrating the configuration of a resonator in a chip illustrated in FIG. 6.

FIG. 8 is a sectional view taken along line VIII-VIII in FIG. 7.

FIG. 9 is a circuit diagram schematically illustrating the configuration of a splitter as an example of use of the acoustic wave filter illustrated in FIG. 1A.

FIG. 10 is a circuit diagram schematically illustrating the configuration of a communication apparatus as another example of use of the acoustic wave filter illustrated in FIG. 1A.

FIG. 11A is a block diagram schematically illustrating the configuration of a filter as another example of use of the acoustic wave filter illustrated in FIG. 1A, and FIGS. 11B and 11C are diagrams illustrating characteristics of the filter illustrated in FIG. 11A.

FIG. 12 is a diagram illustrating an effect of a thickness of a piezoelectric film upon a maximum value of an impedance phase.

FIG. 13 is a diagram illustrating an effect of a thickness of an acoustic film upon the maximum value of the impedance phase.

### DESCRIPTION OF EMBODIMENTS

Contents described in International Publication No. 2019/009246 (PCT/JP2018/025071; hereinafter referred to as prior application 1) may be incorporated herein by reference. Prior application 1 was applied by the applicant of the present disclosure, and part of the inventors of prior application 1 is the inventor of the present disclosure.

An acoustic wave filter according to an embodiment will be described hereinafter with reference to the drawings. The drawings used in the following description are schematic diagrams, and dimensions, ratios, and the like in the drawings are not necessarily the same as in reality.

### <Acoustic Wave Filter>

### (Overall Configuration of Acoustic Wave Filter)

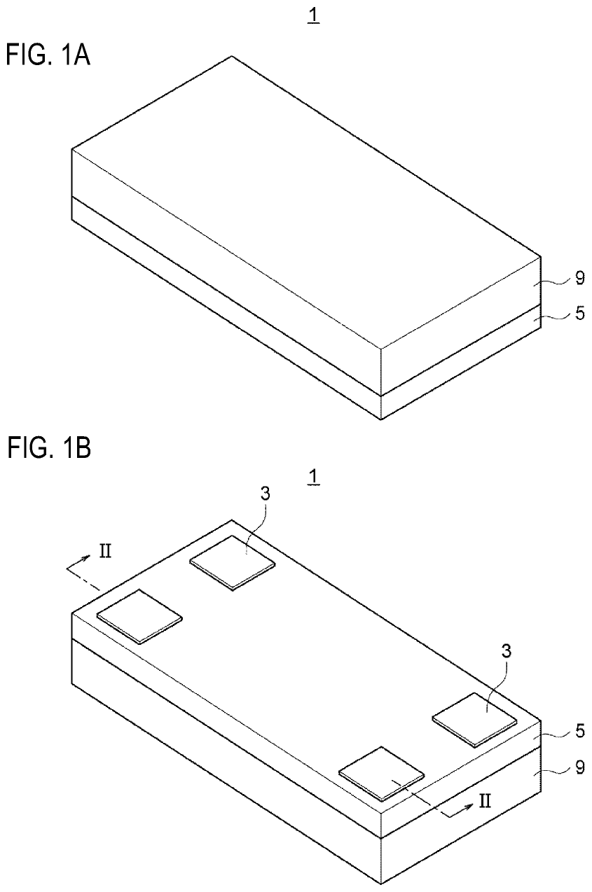

FIG. 1A is a perspective diagram illustrating the appearance of an acoustic wave filter 1 (might be simply referred to as a “filter 1” hereinafter) viewed from an upper surface side according to the embodiment. FIG. 1B is a perspective diagram illustrating the appearance of the filter 1 viewed from a lower surface side. Any direction of the filter 1 may be defined as upward or downward, but an upward direction of a page of FIG. 1B might be defined as upward and a term such as an upper surface or a lower surface might be used for convenience.

The filter 1 is configured, for example, as a chip-shaped member to be mounted on a surface. In the illustrated example, an external shape of the filter 1 is substantially rectangular parallelepipedal. A plurality of external terminals 3 are exposed from a lower surface with an appropriate shape and an appropriate number. The size of the filter 1 may be an appropriate size. For example, the length of a side of the filter 1 is from 1 mm to 10 or more mm.

For example, the filter 1 is arranged such that the lower surface thereof facing a circuit board, which is not illustrated, and mounted on the circuit board by connecting a plurality of pads provided for the circuit board and the plurality of external terminals 3 with each other via a conductive joining material (e.g., solder). A signal is then input to the filter 1 through one of the plurality of external terminals 3, for example, and the input signal is subjected to certain processing (e.g., filtering) and output from another of the plurality of external terminals 3.

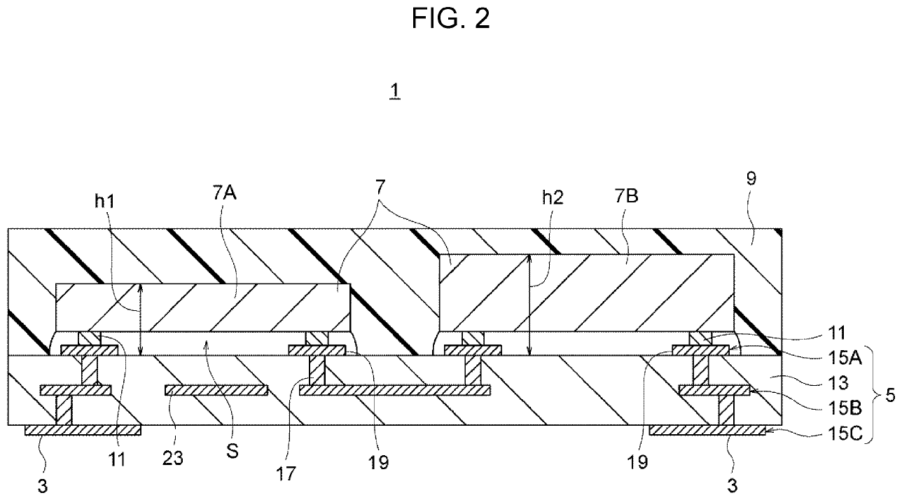

FIG. 2 is a sectional view taken along line II-II in FIG. 1B.

The filter 1 includes a mounting board 5, a plurality of chips (two chips 7A and 7B in the illustrated example) mounted on the mounting board 5, and a sealing part 9 that seals the plurality of chips 7. Each of the chips 7 is connected to the mounting board 5 via a bump 11 located between the chip 7 and the mounting board 5.

The chips 7 are members that directly contribute to filtering employing acoustic waves. The mounting board 5 constitutes, for example, a part of a package for packaging the chips 7 and contributes to electrical mediation between the chips 7 and the outside (the circuit board, which is not illustrated, on which the filter 1 is mounted). The sealing part 9 constitutes, for example, together with the mounting board 5, the package for packaging the chips 7.

### (Mounting Board)

The mounting board 5 is achieved, for example, by a rigid printed wiring board. The mounting board 5 includes, for example, an insulating substrate 13 and various conductors provided in the insulating substrate 13. The various conductors include, for example, a plurality of conductive layers (15A to 15C) substantially parallel to the insulating substrate 13 and through conductors 17 that penetrate the entirety or a part of the insulating substrate 13 in an up-down direction. The plurality of conductive layers include, for example, an upper surface conductive layer 15A on an upper surface of the insulating substrate 13, one or more (one in the illustrated example) internal conductive layers 15B provided inside the insulating substrate 13, and a lower surface conductive layer 15C on a lower surface of the insulating substrate 13.

The insulating substrate 13 is formed, for example, substantially thin rectangular parallelepipedal. The insulating substrate 13 is formed by including, for example, a resin, a ceramic, and/or an amorphous inorganic material. The insulating substrate 13 may be composed of a single material or a composite material such as a substrate obtained by impregnating a base material (reinforcement material) with a resin.

The upper surface conductive layer 15A includes, for example, pads 19 for mounting the chips 7 on the mounting board 5. The lower surface conductive layer 15C includes, for example, the above-described external terminals 3. The through conductors 17 and the internal conductive layer 15B include, for example, wires that connect the pads 19 and the external terminals 3 with each other and wires that connect the pads 19 of the chip 7A and the pads 19 of the chip 7B with each other. The upper surface conductive layer 15A, the internal conductive layer 15B, the lower surface conductive layer 15C, and the through conductors 17 are composed of, for example, a metal such as Cu.

The configuration of the mounting board 5 may be changed from that in the illustrated example in various ways. For example, the internal conductive layer 15B need not be provided. The pads 19 of the chip 7A and the pads 19 of the chip 7B may be connected with each other by the upper surface conductive layer 15A instead of, or in addition to, the internal conductive layer 15B and the through conductors 17. The upper surface conductive layer 15A, the internal conductive layer 15B, the lower surface conductive layer 15C, the through conductors 17, or any selective combination of two or more of these may achieve an inductor, a capacitor, or a circuit that performs appropriate processing.

### (Outline of Chips)

The chips 7 are, for example, substantially rectangular parallelepipedal and arranged in such a way as to face the upper surface of the mounting board 5. Shapes and dimensions of the two or more chips 7 may be the same or different from each other. In the illustrated example, the chip 7A is thinner than the chip 7B. A height h1 from the upper surface of the mounting board 5 (insulating substrate 13) to a surface of the chip 7A opposite from the mounting board 5, therefore, is smaller than a height h2 from the upper surface of the mounting board 5 (insulating substrate 13) to a surface of the chip 7B opposite from the mounting board 5.

### (Bumps)

The bumps 11 are located between the chips 7 and the pads 19 and connect the chips 7 and the pads 19 with each other. As a result, the chips 7 are fixed on the mounting board 5 and electrically connected to the mounting board 5. The bumps 11 are composed of, for example, solder. The solder may contain lead or be free of lead. The bumps 11 may be composed of a conductive adhesive, instead. Since the bumps 11 are located between the chips 7 and the pads 19, there are gaps (spaces S) between the chips 7 and the insulating substrate 13.

### (Sealing Part)

The sealing part 9 is provided in such a way as to cover all of the two or more chips 7 on the mounting board 5, for example, and in contact with peripheral surfaces and the upper surfaces of the chips 7. The gaps between the chips 7 and the insulating substrate 13, however, are not filled with the sealing part 9 and remain as the spaces S. As a result, for example, vibration of piezoelectric films, which will be described later, of the chips 7 (i.e., propagation of acoustic waves) is facilitated. The spaces S may be filled with an appropriate gas (e.g., air or an inert gas) or may be a vacuum. Unlike in the illustrated example, the sealing part 9 may be separated from a part (e.g., a part on a side of the mounting board 5) or the entirety of the peripheral surfaces of the chips 7 or may cover only the peripheral surfaces of the chips 7 without covering the upper surfaces.

An external shape of the sealing part 9 is formed, for example, substantially rectangular parallelepipedal. A shape and size of the sealing part 9 viewed in plan is, for example, the same as a planar shape of the mounting board 5, and side surfaces of the sealing part 9 are substantially aligned with side surfaces of the mounting board 5. An upper surface of the sealing part 9 (a surface opposite from the mounting board 5) is, for example, flat. In other words, a height from the upper surface of the mounting board 5 to the upper surface of the sealing part 9 is the same between a position of the chip 7A and a position of the chip 7B.

The sealing part 9 is composed of, for example, a resin. The resin is, for example, a thermosetting resin. The thermosetting resin is, for example, epoxy resin, phenol resin, or polyimide resin. The resin may be mixed with a filler including insulating particles composed of a material whose thermal expansion coefficient is lower than that of the resin. The material for the insulating particles is, for example, silica, alumina, phenol, polyethylene, fiberglass, or graphite. The sealing part 9 may be composed of a material other than a resin, such as an amorphous inorganic material, instead.

Relative magnitudes of linear expansion coefficients and Young's moduli of the chips 7, the sealing part 9, and the mounting board 5, for example, may be appropriately determined. For example, the linear expansion coefficient of the sealing part 9 is higher than that of the chips 7, but Young's modulus of the sealing part 9 is lower than that of the chips 7.

### (Configuration of Ladder Filter)

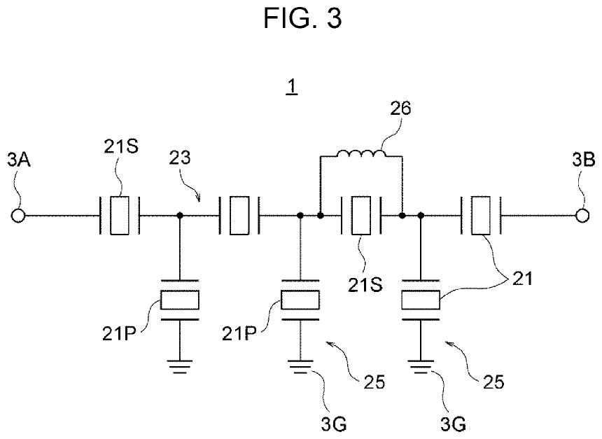

FIG. 3 is a circuit diagram schematically illustrating an outline of the electrical configuration of the filter 1.

The above-described plurality of external terminals 3 include, for example, an input external terminal 3A to which signals are input from the outside (e.g., the circuit board, which is not illustrated, on which the filter 1 is mounted), an output external terminal 3B that outputs signals to the outside, and reference potential external terminals 3G to which a reference potential is applied. The filter 1 removes unnecessary signals from signals input to the input external terminal 3A (attenuates unnecessary signals) and outputs resultant signals to the output external terminal 3B. The removed unnecessary signals are released to the reference potential external terminals 3G.

The filter 1 may be, for example, a band-pass filter or a band-elimination filter. The filter 1 as a band-pass filter passes signals in a certain band (passband) to the output external terminal 3B from the input external terminal 3A. The filter 1 as a band-elimination filter attenuates (removes) signals in a certain band (stopband) among the signals that pass from the input external terminal 3A to the output external terminal 3B.

The filter 1 is achieved, for example, by a ladder filter in which a plurality of resonators 21 (21S and 21P, more specifically) are connected to one another in a ladder configuration. More specifically, for example, the filter 1 includes a plurality of (four in the illustrated example) serial resonators 21S connected in series with one another between the input external terminal 3A and the output external terminal 3B and a plurality of (three in the illustrated example) parallel resonators 21P that connect a line of the serial resonators 21S and reference potential parts (the reference potential external terminals 3G here) to each other.

A line including the plurality of serial resonators 21S from the input external terminal 3A to the output external terminal 3B might be referred to as a series arm 23. A line including one parallel resonator 21P from the series arm 23 to each of the reference potential parts might be referred to as a parallel arm 25. The series arm 23 contributes to transmission of signals within the passband or outside the stopband. The parallel arm 25 contributes to transmission of signals outside the passband or within the stopband to the reference potential external terminals 3G.

The number of serial resonators 21S and the number of parallel resonators 21P (parallel arms 25) may be appropriately determined. Although the plurality of serial resonators 21S and the plurality of parallel resonators 21P are provided in the illustrated example, one serial resonator 21S and one parallel resonator 21P may be provided, instead. In addition, although the resonator 21 closest to the input external terminal 3A is a serial resonator 21S in the illustrated example, the resonator 21 closest to the input external terminal 3A may be a parallel resonator 21P, instead. The same holds for the output external terminal 3B. In the chips 7 or the filter 1, some or all of the plurality of parallel resonators 21P may be connected to the same reference potential part, individually connected to a plurality of reference potential parts short-circuited to one another, or individually connected to a plurality of reference potential parts that are not short-circuited to one another.

When the plurality of resonators 21 are connected in a ladder configuration in the description of the present embodiment, for example, the series arm 23 (i.e., one serial resonator 21S or a plurality of serial resonators 21S connected in series with one another) is electrically connected between the input external terminal 3A and the output external terminal 3B and one or more parallel arms 25 (i.e., one or more parallel resonators 21P) are electrically connected between an input side or an output side of one or more serial resonators 21S and the reference potential parts as described above.

The filter 1 may also include components other than the resonators 21. For example, an inductor and/or a capacitor may be included at an appropriate position. In the illustrated example, an inductor 26 connected in parallel with the serial resonators 21S is illustrated. The inductor 26 may be achieved, for example, by a conductor (e.g., the internal conductive layer 15B as illustrated in FIG. 2) provided in the mounting board 5 or a conductor provided for the chips 7. The inductor 26 contributes to, for example, enlarging the passband of the filter 1 as a band-pass filter or the stopband of the filter 1 as a band-elimination filter.

The filter 1 as a band-pass filter and the filter 1 as a band-elimination filter have different relationships between a resonant frequency of the serial resonators 21S and a resonant frequency of the parallel resonators 21P. The relationships between the resonant frequency of the serial resonators 21S and the resonant frequency of the parallel resonators 21P in a band-pass filter and a band-elimination filter will be described hereinafter in this order.

### (Band-Pass Filter)

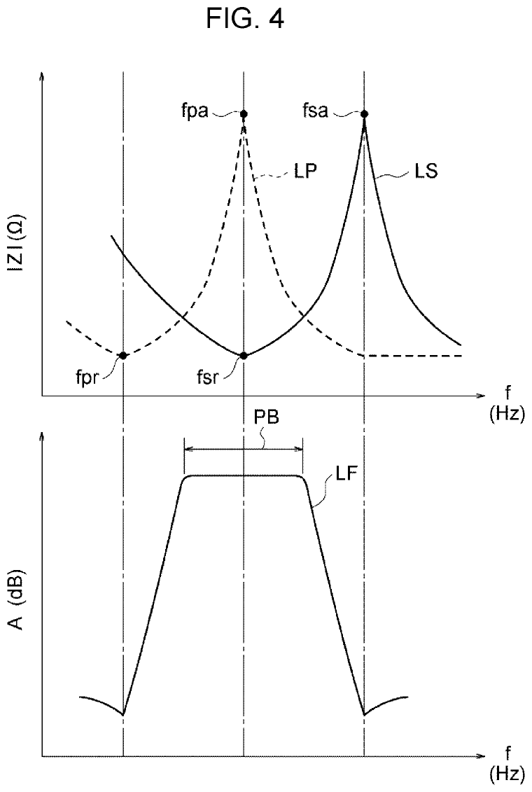

FIG. 4 is a diagram for describing an example of setting of a resonant frequency for the filter 1 as a band-pass filter.

In an upper graph of FIG. 4, a horizontal axis represents frequency f (Hz), and a vertical axis represents an absolute value |Z| (Ω) of impedance. A line LS represents impedance of the serial resonators 21S. A line LP represents impedance of the parallel resonators 21P. In a lower graph of FIG. 4, a horizontal axis represents frequency f (Hz), and a vertical axis represents attenuation A (dB). A line LF represents attenuation of the filter 1. The horizontal axis of the upper graph of FIG. 4 and the horizontal axis of the lower graph of FIG. 4 match.

In a frequency characteristic of impedance relating to a resonator 21 that is an acoustic wave resonator, a resonance point at which impedance becomes the smallest and an anti-resonance point at which impedance becomes the largest appear. Frequencies at which the resonance point and the anti-resonance point appear will be referred to as a resonant frequency (fsr, fpr) and an anti-resonant frequency (fsa, fpa), respectively. An anti-resonant frequency of a resonator 21 is, for example, higher than a resonant frequency of the resonator 21.

Resonant frequencies and anti-resonant frequencies of the serial resonators 21S and the parallel resonators 21P are set such that the resonant frequency fsr of the serial resonators 21S (line LS) and the anti-resonant frequency fpa of the parallel resonators 21P (line LP) become substantially the same. As a result, the filter 1 (line LF) functions as a band-pass filter whose passband PB is slightly narrower than a frequency range (attenuation range) between the resonant frequency fpr of the parallel resonators 21P and the anti-resonant frequency fsa of the serial resonators 21S. The plurality of serial resonators 21S basically have the same resonant frequency and the same anti-resonant frequency. The same holds for the plurality of parallel resonators 21P.

As understood from the above description, the resonant frequency of the serial resonators 21S is higher than that of the parallel resonators 21P in the filter 1 as a band-pass filter. The same holds for the anti-resonant frequencies.

### (Band-Elimination Filter)

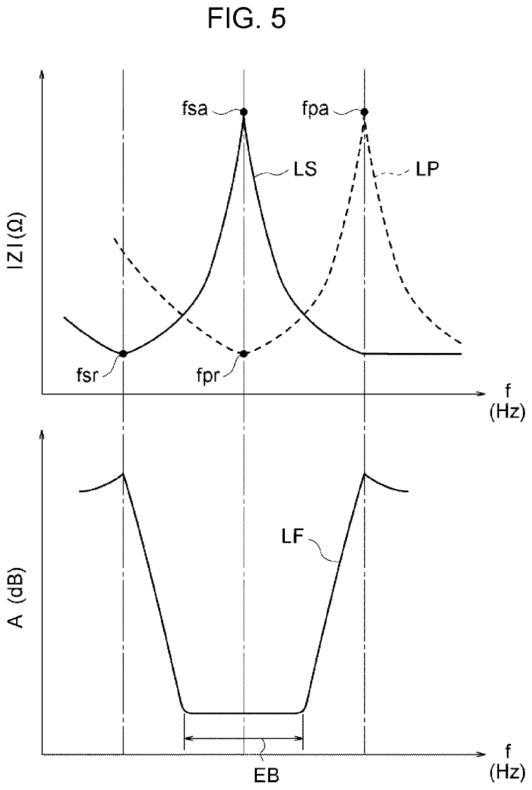

FIG. 5 is a diagram for describing an example of setting of a resonant frequency for the filter 1 as a band-elimination filter.

FIG. 5 is a diagram similar to FIG. 4. As in FIG. 4, the line LS represents the impedance of the serial resonators 21S, the line LP represents the impedance of the parallel resonators 21P, and the line LF represents the attenuation of the filter 1.

In the filter 1 as a band-elimination filter, resonant frequencies and anti-resonant frequencies are set such that the resonant frequency fpr of the parallel resonators 21P (line LP) and the anti-resonant frequency fsa of the serial resonators 21S (line LS) become substantially the same. As a result, the filter (line LF) functions as an elimination filter whose stopband EB is slightly narrower than a frequency range from the resonant frequency fsr of the serial resonators 21S to the anti-resonant frequency fpa of the parallel resonators 21P. The plurality of serial resonators 21S basically have the same resonant frequency and the same anti-resonant frequency. The same holds for the plurality of parallel resonators 21P.

As understood from the above description, in the filter 1 as a band-elimination filter, the resonant frequency of the serial resonators 21S is lower than that of the parallel resonators 21P in contrast to the filter 1 as a band-pass filter. The same holds for the anti-resonant frequencies.

### (Distribution of Resonators)

As described above, the filter 1 includes the plurality of resonators 21 connected with each other in a ladder configuration in electrical terms. The plurality of resonators 21 are distributed between the two or more chips 7 included in the filter 1. The plurality of resonators 21 are electrically connected to one another, for example, via the mounting board 5 on which the chips 7 are mounted. Details will be described hereinafter.

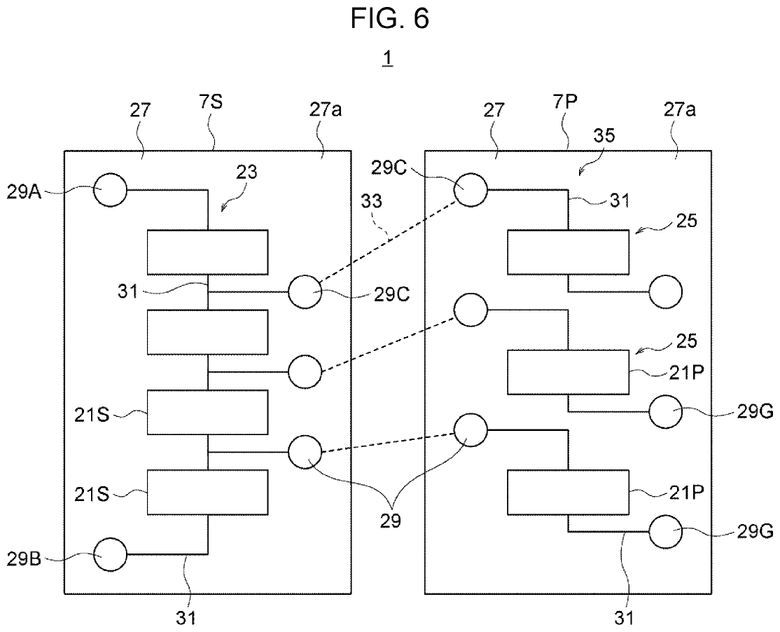

FIG. 6 is a plan view schematically illustrating surfaces of the chips 7A and 7B facing the mounting board 5.

One of chips 7S and 7P illustrated in the figure is one of the chips 7A and 7B illustrated in FIG. 2. Another of the chips 7S and 7P is the other of the chips 7A and 7B.

The chips 7 include, for example, basically insulating fixed substrates 27 that constitute most of external shapes of the chips 7. The resonators 21, a plurality of chip terminals 29 (more specifically, 29A to 29C and 29G), and a plurality of wires 31 connecting the resonators 21 and the chip terminals 29 to each other are located on surfaces (functional surfaces 27a) of the fixed substrates 27 that face the mounting board 5.

The chip terminals 29 and the wires 31 are achieved, for example, by a conductive layer 35 located on the functional surfaces 27a. The plurality of chip terminals 29 face the pads 19 (FIG. 2) of the mounting board 5, for example, and are connected with the pads 19 by the bumps 11 located between the chip terminals 29 and the pads 19. As a result, each of the chip terminals 29 is electrically connected to one of the external terminals 3 (FIGS. 1 to 3) or another chip terminal 29.

The plurality of chip terminals 29 include, for example, an input chip terminal 29A, an output chip terminal 29B, reference potential chip terminals 29G, and connection chip terminals 29C. The input chip terminal 29A is electrically connected to the input external terminal 3A (FIG. 3) via one of the pads 19. The output chip terminal 29B is electrically connected to the output external terminal 3B via one of the pads 19. The reference potential chip terminals 29G are electrically connected to the reference potential external terminals 3G (FIG. 3) via some of the pads 19. The connection chip terminals 29C of the chip 7S are electrically connected to the connection chip terminals 29C of the chip 7P via some of the pads 19. In FIG. 6, wires 33 expressed in broken lines schematically indicate electrical paths achieved by conductors of the bumps 11 and the mounting board 5.

As understood from comparison between FIGS. 3 and 6, all (four in the illustrated example) the serial resonators 21S are provided on the chip 7S. All (three in the illustrated example) the parallel resonators 21P are provided on the chip 7P. The plurality of resonators 21 are connected to one another in a ladder configuration, for example, by the plurality of wires 31, the plurality of connection chip terminals 29C, and the plurality of wires 33.

A resonant frequency of the resonators 21 on the chip 7S (one of the chips 7A and 7B) and a resonant frequency of the resonators 21 on the chip 7P (the other of the chips 7A and 7B), therefore, are different from each other. More specifically, in the filter 1 as a band-pass filter, a resonant frequency of the chip 7S is higher than that of the chip 7P. Conversely, in the filter 1 as a band-elimination filter, the resonant frequency of the chip 7S is lower than that of the chip 7P.

FIG. 6 is just a schematic diagram for describing how the serial resonators 21S and the parallel resonators 21P are distributed between the two chips 7. Sizes of the plurality of resonators 21 are the same, the plurality of resonators 21 are arranged in lines with the same pitch, and shapes of the wires 31 are simplified to simplify the diagram. In practice, the resonators 21, the chip terminals 29, and the wires 31 may employ any shapes, sizes, arrangement, and the like different from those employed in the figure. In addition, some components, such as a chip terminal 29 and wires 31 for connecting in parallel the inductor 26 illustrated in FIG. 3 to the serial resonators 21S, are omitted in FIG. 6. When the resonators 21 can be arranged in lines as in FIG. 6, however, other resonators 21 are not located in a propagation direction of acoustic waves, and noise and the like can be suppressed. Especially when high-frequency signals whose frequencies exceed 5 GHz, which require acoustic films, are used, not conventional acoustic waves, which propagate along a surface, but plate waves are used. This arrangement is effective because an effect of an overlap of resonators in the propagation direction of acoustic waves in this case can be even greater.

When the serial resonators 21S are arranged in a line, the width of the wires 31 may be increased to the length of the resonators in the propagation direction. As a result, losses can be reduced because the electrical resistance of the wires can be reduced. This arrangement will be effective in the case of next-generation devices that employ high-frequency signals whose frequencies exceed 5 GHz, because input power will be large.

By dividing a chip 7 into two or more pieces in a single filter, design can thus be optimized for each of the chips.

### (Configuration of Resonators)

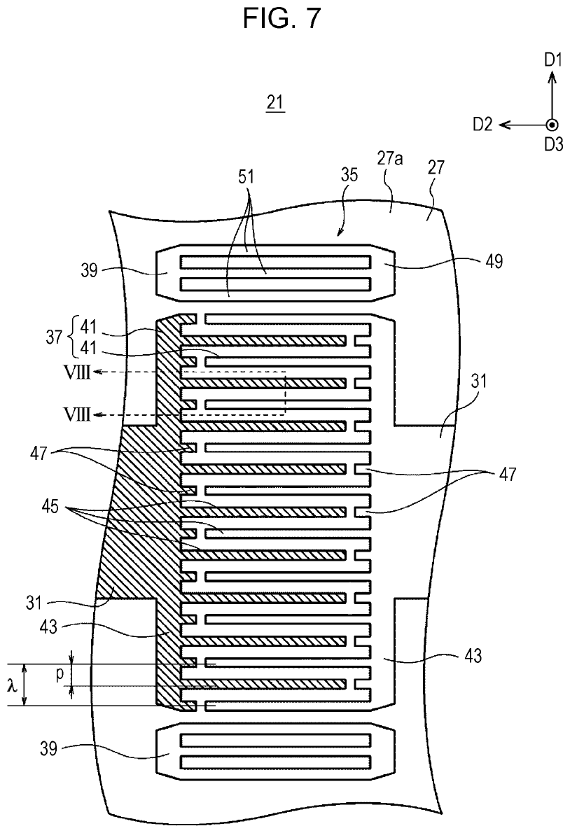

FIG. 7 is a plan view schematically illustrating the configuration of one of the resonators 21 and corresponds to a diagram illustrating an enlargement of a part of one of the functional surfaces 27a illustrated in FIG. 6.

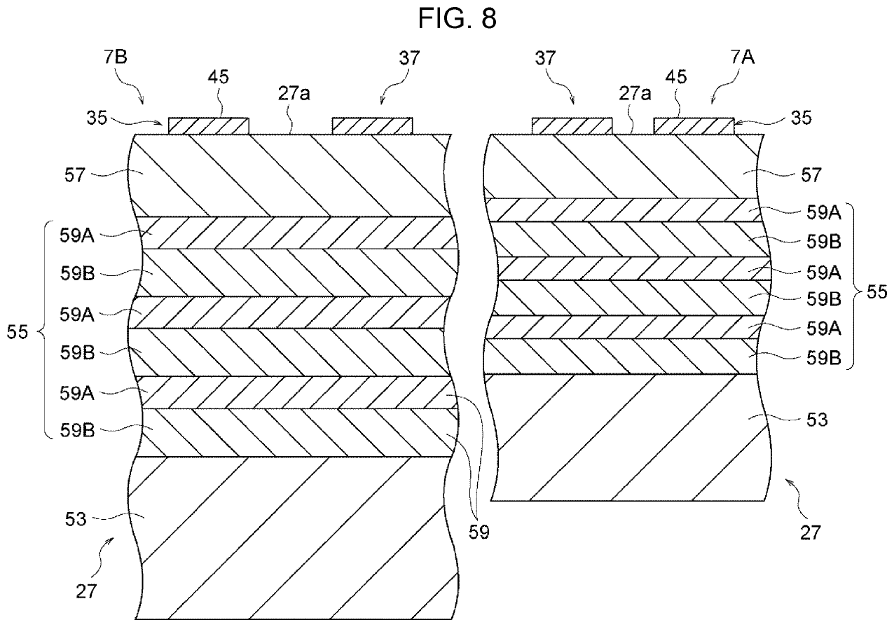

In FIG. 7, a Cartesian coordinate system defined by a D1 axis, a D2 axis and a D3 axis is given for convenience. When the resonators 21 are described with reference to FIG. 7 and FIG. 8, which will be referred to later, a term such as an upper surface or a lower surface might be used with a positive direction of the D3 axis defined as upward. The D1 axis is defined as being parallel to the propagation direction of acoustic waves that propagate along the functional surface 27a. The D2 axis is defined as being parallel to the functional surface 27a and perpendicular to the D1 axis. The D3 axis is defined as being perpendicular to the functional surface 27a.

The resonator 21 is achieved by a so-called one-port acoustic wave resonator. For example, the resonator 21 outputs a signal input from one of two wires 31 illustrated in both sides of a page from another of the two wires 31. At this time, the resonator 21 converts an electrical signal into an acoustic wave and an acoustic wave into an electrical signal.

The resonator 21 includes, for example, the above-described fixed substrate 27 (at least a part thereof on a side of the functional surface 27a), an excitation electrode 37 located on the functional surface 27a, and a pair of reflectors 39 located on both sides of the excitation electrode 37. As illustrated in FIG. 6, the fixed substrate 27 is sometimes shared by a plurality of resonators 21. In the following description, a combination of an excitation electrode 37 and one of reflectors 39 (an electrode part of the resonator 21) might be expressed as if it were a resonator 21 for convenience. The excitation electrode 37 and the reflectors 39 are achieved by the above-described conductive layer 35.

The functional surface 27a has piezoelectricity. The excitation electrode 37 contributes, for example, to generating, on the functional surface 27a, an acoustic wave having a waveform according to a waveform of an electrical signal input to the resonator 21. The frequency characteristics of impedance illustrated in FIGS. 4 and 5 are achieved by using a resonance phenomenon of this acoustic wave. The reflectors 39 contribute to reducing leakage of acoustic waves and improving efficiency of conversion between electrical signals and acoustic waves.

### (Electrode Part of Resonator)

The excitation electrode 37 is achieved by interdigital transducer (IDT) electrodes and includes a pair of interdigital electrodes 41. One of the interdigital electrodes 41 is hatched to increase visibility. Each of the interdigital electrodes 41 includes, for example, a busbar 43, a plurality of electrode fingers 45 extending from the busbar 43 parallel to one another, and dummy electrodes 47 that protrude from the busbar 43 between the plurality of electrode fingers 45. The pair of interdigital electrodes 41 are arranged such that the plurality of electrode fingers 45 engage (cross) each other.

The busbar 43 is, for example, formed in a long shape extending linearly in the propagation direction (D1 direction) of acoustic waves with a substantially constant width. The pair of busbars 43 face each other in a direction (D2 direction) perpendicular to the propagation direction of acoustic waves. The width of the busbars 43 may vary, or the busbars 43 may be inclined relative to the propagation direction of acoustic waves.

Each of the electrode fingers 45 is formed, for example, in a long shape extending linearly in the direction (D2 direction) perpendicular to the propagation direction of acoustic waves with a substantially constant width. In each of the interdigital electrodes 41, the plurality of electrode fingers 45 are arranged in the propagation direction of acoustic waves. The plurality of electrode fingers 45 of one of the interdigital electrodes 41 and the plurality of electrode fingers 45 of the other interdigital electrode 41 are basically arranged alternately.

Pitch p (e.g., a distance between centers of two adjacent electrode fingers 45) of the plurality of electrode fingers 45 is basically constant in the excitation electrode 37. The excitation electrode 37 may include a part unique in terms of the pitch p. The unique part may be, for example, a small-pitch part where the pitch p is smaller than in most of the excitation electrode 37 (e.g., 80% or higher), a large-pitch part where the pitch p is larger than in most of the excitation electrode 37, or a thinning part where a few electrode fingers 45 are essentially thinned out.

In the following description, the pitch p refers to pitch in a part (most of the plurality of electrode fingers 45) other than the unique part unless otherwise noted. When pitch varies in most of the plurality of electrode fingers 45 other than the unique part, an average of the pitch of most of the plurality of electrode fingers 45 may be used as a value of the pitch p.

The number of electrode fingers 45 may be appropriately determined in accordance with electrical characteristics or the like required for the resonator 21. Since FIG. 7 is a schematic diagram, the electrode fingers 45 are fewer than in reality. In practice, more electrode fingers 45 than illustrated may be provided. The same holds for strip electrodes 51 of the reflectors 39, which will be described later.

The length of the plurality of electrode fingers 45 is, for example, the same. The excitation electrode 37 may be subjected to so-called apodization, where the length (i.e., cross width) of the plurality of electrode fingers 45 changes depending on a position in the propagation direction. The length and width of the electrode fingers 45 may be appropriately determined in accordance with required electrical characteristics or the like.

The dummy electrodes 47 protrude, for example, in the direction perpendicular to the propagation direction of acoustic waves with a substantially constant width. The width is, for example, the same as that of the electrode fingers 45. The plurality of dummy electrodes 47 are arranged with the same pitch as that of the plurality of electrode fingers 45, and ends of the dummy electrodes 47 of one of the interdigital electrodes 41 face ends of the electrode fingers 45 of the other interdigital electrode 41 with gaps interposed therebetween. The excitation electrode 37 need not include the dummy electrodes 47.

The pair of reflectors 39 are located on both sides of the plurality of excitation electrodes 37 in the propagation direction of acoustic waves. Each of the reflectors 39 may be, for example, electrically floating or given a reference potential. Each of the reflectors 39 is formed, for example, in a lattice. That is, each of the reflectors 39 includes a pair of busbars 43 facing each other and a plurality of strip electrodes 51 extending between the pair of busbars 43. The pitch of the plurality of strip electrodes 51 and the pitch of an electrode finger 45 and a strip electrode 51 adjacent to each other are basically the same as the pitch of the plurality of electrode fingers 45.

When a voltage is applied to the pair of interdigital electrodes 41, the plurality of electrode fingers 45 apply the voltage to the functional surface 27a having piezoelectricity, and the functional surface 27a vibrates. As a result, an acoustic wave that propagates in the D1 direction is excited. The acoustic wave is reflected by the plurality of electrode fingers 45. A standing wave whose half-wavelength (λ/2) is approximately the pitch p of the plurality of electrode fingers 45 is generated. An electrical signal generated by the standing wave in a piezoelectric film 57 is obtained by the plurality of electrode fingers 45. By this principle, the resonator 21 functions as a resonator whose resonant frequency is a frequency of an acoustic wave whose half-wavelength is the pitch p. An anti-resonant frequency is determined by the resonant frequency and a capacitance ratio.

As understood from the above description, in principle and/or as a rule, the smaller the pitch p, the higher the resonant frequency (and the anti-resonant frequency). More specifically, a relationship between the resonant frequency and the pitch p is close to an inverse proportional relationship. In other words, the pitch p of a resonator 21 whose resonant frequency is high is smaller than that of a resonator 21 whose resonant frequency is low. As understood from the following description, however, this is not necessarily true in the present embodiment.

Although not particularly illustrated, a resonator 21 may be achieved by dividing the configuration illustrated in FIG. 7 into two or more pieces. For example, a resonator 21 may include a plurality of combinations of an excitation electrode 37 and a pair of reflectors 39, and the plurality of excitation electrodes 37 may be connected in series with one another. In this case, for example, a voltage applied to each of the excitation electrode 37 can be reduced, and overall power resistance of the resonator 21 can be improved. Whether each of the serial resonators 21S includes a plurality of excitation electrodes 37 may be determined, for example, on the basis of a position at which a parallel arm 25 is connected. If a parallel arm 25 is not connected between two excitation electrodes 37 connected in series with each other, for example, the two excitation electrodes 37 achieve the same serial resonator 21S.

### (Fixed Substrates and Conductive Layers)

FIG. 8 is a sectional view taken along line VIII-VIII in FIG. 7. A cross-section of the chip 7A is illustrated in a right part of a page, and a cross-section of the chip 7B is illustrated in a left part of the page. Scales of the two cross-sections are the same.

First, items common to the chip 7A and the chip 7B will be described. The fixed substrates 27 each include, for example, a support substrate 53, a multilayer film 55 located on the support substrate 53, and the piezoelectric film 57 located on the multilayer film 55. An upper surface of the piezoelectric film 57 achieves the above-described functional surface 27a. That is, the conductive layer 35 (the excitation electrodes 37 and the like) are located on the piezoelectric film 57.

The piezoelectric film 57 is, for example, a part that directly contributes to conversion between electrical signals and acoustic waves. The multilayer film 55 contributes, for example, to reflecting acoustic waves propagating through the piezoelectric film 57 and trapping energy of the acoustic waves in the piezoelectric film 57. The support substrate 53 contributes, for example, to increasing the strength of the multilayer film 55 and the piezoelectric film 57.

In the fixed substrate 27 having such a configuration, for example, acoustic waves may be ones in a slab mode. Propagation speed (sound speed) of acoustic waves in the slab mode is higher than that of general surface acoustic waves (SAWs). For example, the propagation speed of general SAWs is 3,000 to 4,000 m/s, whereas the propagation speed of acoustic waves in the slab mode is 10,000 m/s or higher. As a result, resonance and/or filtering in a relatively high frequency range can be achieved more easily. For example, a resonant frequency of 5 GHz or higher can be achieved with a pitch p of 1 μm or larger.

Although not illustrated, the upper surface of the piezoelectric film 57 may be covered by an insulating protection film from above the conductive layer 35 (except for the chip terminals 29), instead. A material for the protection film is, for example, SiO₂ or Si₃N₄. The protection film may be obtained by stacking a plurality of layers composed of these materials on one another. The protection film may simply reduce corrosion of the conductive layer 35 or contribute to temperature compensation. When the protection film is provided, for example, an additional film composed of an insulator or a metal may be provided on upper surfaces or lower surfaces of the excitation electrodes 37 and the reflectors 39, in order to improve a reflection coefficient of acoustic waves.

A specific configuration of each of the layers of the chips 7 is, for example, as follows.

### (Support Substrate)

The support substrate 53 does not directly affect electrical characteristics of the resonator 21. A material for and dimensions of the support substrate 53, therefore, may be appropriately determined. The material for the support substrate 53 is, for example, an insulating material, which is, for example, a resin or a ceramic. Alternatively, the support substrate 53 may be composed of a material whose thermal expansion coefficient is lower than that of the piezoelectric film 57 or the like. In this case, for example, a probability that a frequency characteristic of the resonator 21 changes as a result of a change in temperature can be reduced. Such a material is, for example, a semiconductor such as silicon, a single crystal such as sapphire, or a ceramic such as sintered aluminum oxide. The support substrate 53 may be achieved by stacking a plurality of layers composed of different materials on one another, instead. The support substrate 53 is, for example, thicker than the piezoelectric film 57.

### (Multilayer Film)

The multilayer film 55 is achieved by sequentially stacking a plurality of acoustic films 59 on one another. Materials for a plurality of acoustic films 59 stacked on each other are different from each other. In other words, acoustic impedances of the plurality of acoustic films 59 stacked on each other are different from each other. As a result, for example, acoustic waves can be reflected more easily at interfaces between the acoustic films 59 stacked on each other. In the illustrated example, first acoustic films 59A and second acoustic films 59B composed of a material different from a material for the first acoustic films 59A are stacked on each other alternately. That is, the multilayer film 55 is composed of two materials. It is needless to say that the multilayer film 55 may be composed of three or more materials, unlike in the illustrated example.

The materials for the plurality of acoustic films 59 may be appropriately determined in terms of acoustic impedance or the like. For example, acoustic impedance of the material for the second acoustic films 59B may be set higher than that of the material for the first acoustic films 59A. As a result, for example, reflectance of acoustic waves becomes relatively high at the interfaces between the two. More specifically, for example, the material for the first acoustic films 59A may be silicon dioxide (SiO₂). In this case, the material for the second acoustic film 59B may be, for example, tantalum pentoxide (Ta₂O₅), hafnium oxide (HfO₂), zirconium dioxide (ZrO₂), titanium dioxide (TiO₂), or magnesium oxide (MgO).

When a relationship between the acoustic impedances of the first acoustic films 59A and the second acoustic films 59B is as described above, a layer in contact with the piezoelectric film 57 may be, for example, a first acoustic film 59A. A layer in contact with the support substrate 53 may be a first acoustic film 59A or a second acoustic film 59B.

The number of layers stacked in the multilayer film 55 (the number of layers of acoustic films 59) may be appropriately determined. In an example, the number of layers is from 3 to 12. It is needless to say that the number of layers may be 2, or 13 or more. The number of layers may be an even number or an odd number.

Thicknesses of the acoustic films 59 may be appropriately determined. For example, all the acoustic films 59 in each of the chips 7 may have the same thickness, or some or all of the acoustic films 59 may have different thicknesses. In the illustrated example, the plurality of first acoustic films 59A have the same thickness and the plurality of second acoustic films 59B have the same thickness in each of the chips 7. In addition, in this example, the thickness of the first acoustic film 59A and the thickness of the second acoustic film 59B are different from each other. In other words, acoustic films 59 composed of the same material have the same thickness, and acoustic films 59 composed of different materials have different thicknesses. Unlike in the illustrated example, however, the thickness of the first acoustic film 59A and the thickness of the second acoustic film 59B may be the same, the first acoustic films 59A may have different thicknesses, or the second acoustic films 59B may have different thicknesses, instead.

Additional layers may be inserted between acoustic films 59 stacked on each other in order to improve adhesion between the films and/or reduce diffusion. The additional layers are so thin that an effect upon the characteristics is negligible. For example, the thickness of the additional layers is appropriately 1% or lower of 2 p. In the description of the present disclosure, presence of additional layers might be ignored even when such additional layers are provided. The same holds for an interface between the piezoelectric film 57 and the multilayer film 55, for example.

### (Piezoelectric Film)

The piezoelectric film 57 is composed, for example, of a single crystal having piezoelectricity. More specifically, for example, the piezoelectric film 57 is composed of a single crystal of lithium tantalate (LiTaO₃) or a single crystal of lithium niobate (LiNbO₃). A cut angle of the piezoelectric film 57 may be a known cut angle or one of various other angles. For example, the piezoelectric film 57 may be a rotated Y-cut X-propagation film. That is, the propagation direction (D1 direction) of acoustic waves and an X-axis may substantially match (e.g., a difference between the two is)±10°. An inclination angle of a Y-axis relative to a normal (D3 axis) of the piezoelectric film 57 at this time may be appropriately determined.

### (Conductive Layer)

As described above, the conductive layer 35 achieves, for example, the excitation electrodes 37, the reflectors 39, the wires 31, and the chip terminals 29. The entirety or a part of one of these parts may be achieved by a conductive layer other than the conductive layer 35, instead. For example, the entirety of the thickness of the excitation electrodes 37, the reflectors 39, and the wires 31 may be achieved by the conductive layer 35, whereas the chip terminals 29 may be achieved by the conductive layer 35 and another conductive layer stacked on the conductive layer 35.

The conductive layer 35 is composed, for example, of a metal. The metal may be of an appropriate type, such as aluminum (Al) or an alloy mainly composed of Al (Al alloy). The Al alloy is, for example, an aluminum-copper (Cu) alloy. The conductive layer 35 may include a plurality of metal layers, instead. For example, a relatively thin layer composed of titan (Ti) for increasing adhesion between Al or an Al alloy and the piezoelectric film 57 may be provided between the two.

### (Example of Thicknesses)

The thickness of each layer may be appropriately determined. An example will be described hereinafter. As described above, the pitch of the electrode fingers 45 is denoted by p. At this time, the thickness of the piezoelectric film 57 may be from 0.3 p to 0.6 p. The thickness of the first acoustic film 59A may be 0.10 p or more, 0.14 p or more, 0.28 p or less, or 0.26 p or less, and these lower limits and upper limits may be appropriately combined together. The thickness of the second acoustic film 59B may be 0.08 p or more, 1.90 p or more, 2.00 p or less, or 0.20 p or less, and these lower limits and upper limits may be appropriately combined together, insofar as no contradiction is caused. The thickness of the conductive layer 35 may be, for example, from 0.04 p to 0.17 p.

### (Differences and Similarities Between Chips)

As described above, the resonant frequency of the resonators 21 is different between the chips 7A and 7B. It is assumed here that the resonant frequency of the resonators 21 included in the chip 7A is higher than that of the resonators 21 included in the chip 7B. In the filter 1 as a band-pass filter, for example, therefore, the chip 7S including the serial resonators 21S is the chip 7A, and the chip 7P including the parallel resonators 21P is the chip 7B. In the filter 1 as a band-elimination filter, conversely, the chip 7P including the parallel resonators 21P is the chip 7A, and the chip 7S including the serial resonators 21S is the chip 7B.

The chip 7A and the chip 7B are the same in terms of the total number of layers of the plurality of acoustic films 59 and the piezoelectric film 57, order of arrangement of materials in a stacking direction, and a ratio of the thicknesses of the films. The chip 7A and the chip 7B, on the other hand, are different from each other in terms of the total thickness of the plurality of acoustic films 59 and the piezoelectric film 57. More specifically, the total thickness of the plurality of acoustic films 59 and the piezoelectric film 57 in the chip 7A is smaller than that of the plurality of acoustic films 59 and the piezoelectric film 57 in the chip 7B. In other words, the configuration of the multilayer film 55 and the piezoelectric film 57 of the chip 7A can be obtained by reducing the configuration of the multilayer film 55 and the piezoelectric film 57 of the chip 7B in size in a thickness direction while maintaining the ratio of the films.

In the illustrated example, for example, the total number of layers is 7 in both chips 7 (the six acoustic films 59 and the one piezoelectric film 57). The total number of layers of the plurality of acoustic films 59 and the piezoelectric film 57, therefore, is the same between the chip 7A and the chip 7B.

Furthermore, in the illustrated example, SiO₂ is taken as an example of the material for the first acoustic films 59A, Ta₂O₅ is taken as an example of the material for the second acoustic films 59B, and LiTaO₃ is taken as an example of the material for the piezoelectric film 57. At this time, in both chips 7, layers are stacked from below in order of Ta₂O₅, SiO₂, Ta₂O₅, SiO₂, Ta₂O₅, SiO₂, and LiTaO₃. A cut angle of LiTaO₃ is the same between the chip 7A and the chip 7B. The chip 7A and the chip 7B, therefore, are the same in terms of order in which the materials for the plurality of acoustic films 59 and the piezoelectric film 57 are arranged in the stacking direction.

As described above, with respect to a layer (piezoelectric film 57) whose cut angle affects the frequency characteristic of the filter 1, a material may be regarded as being the same when the cut angle is the same. Conversely, items of each layer whose effects upon the frequency characteristic of the filter 1 may be negligible need not be taken into consideration in a determination whether a material is the same.

In the illustrated example, a ratio of the thicknesses of the lower to higher layers expressed as follows is the same between the chip 7A and the chip 7B: Thickness of the second acoustic film 59B (lowest layer):Thickness of the first acoustic film 59A (second lowest layer):Thickness of the second acoustic film 59B (third lowest layer):Thickness of the first acoustic film 59A (fourth lowest layer):Thickness of the second acoustic film 59B (fifth lowest layer):Thickness of the first acoustic film 59A (sixth lowest layer):Thickness of the piezoelectric film 57. The chip 7A and the chip 7B, therefore, are the same in terms of the ratio of the thicknesses of the plurality of acoustic films 59 and the piezoelectric film 57.

Even though the ratio of the films in the chip 7A and the ratio of the films in the chip 7B are the same, it is needless to say that there may be differences due to precision of fabrication and allowable differences in view of the spirit of the present disclosure, and the like. When a difference between a ratio (thickness of a first film/thickness of a second film) in the chip 7A and a ratio (thickness of a film corresponding to the first film/thickness of a film corresponding to the second film) in the chip 7B is 5% or lower of an average of the ratio in the chip 7A and the ratio in the chip 7B, for example, the ratio in the chip 7A and the ratio in the chip 7B may be regarded as being the same.

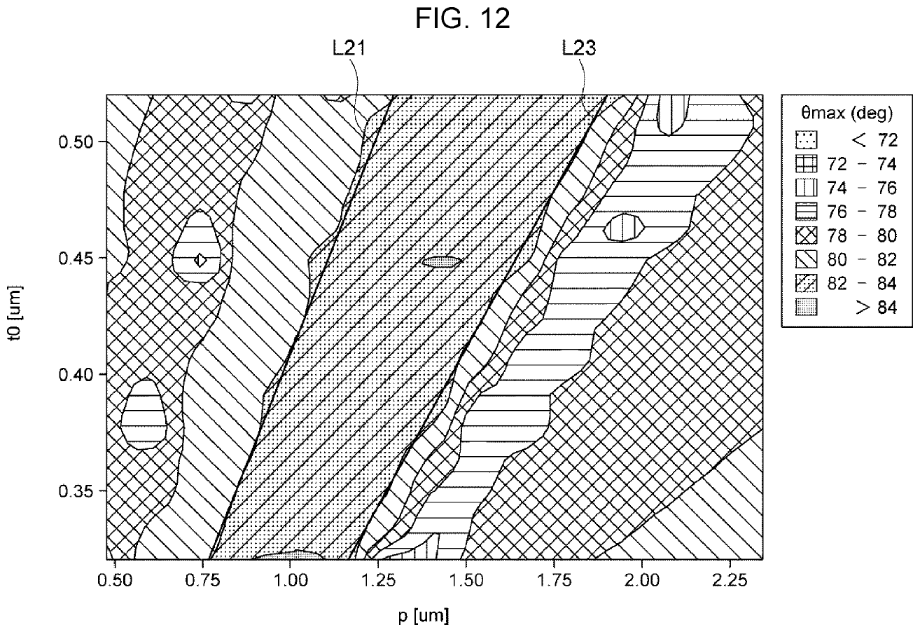

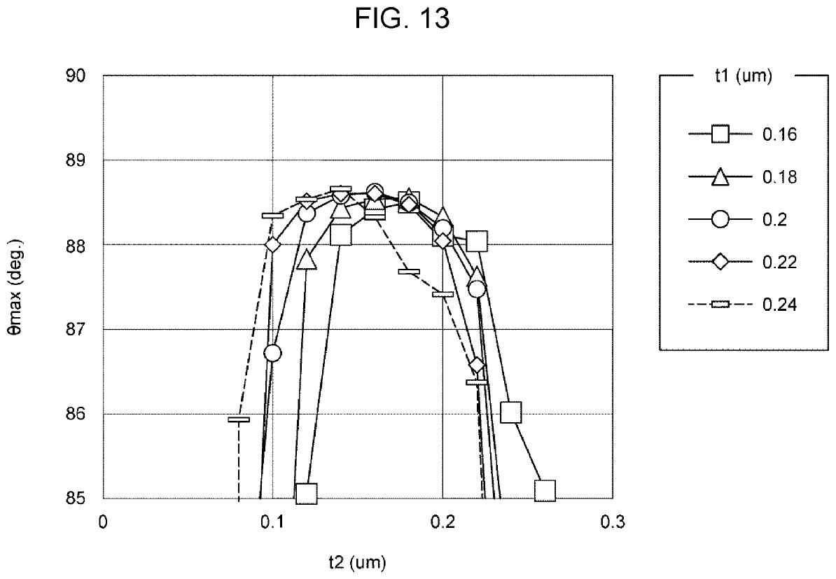

Even if the thickness of each of the films varies with the difference in the ratio of the thicknesses of the films remaining within a range of 5% or lower, characteristics as the resonator 21 can be maintained. For example, FIGS. 12 and 13 illustrate results of simulations of an effect of the thickness of the piezoelectric film and the thickness of the acoustic films, respectively, upon a maximum value of an impedance phase.

### (Thickness of Piezoelectric Film)

The pitch p of the electrode fingers 45 and a thickness t0 of the piezoelectric film 57 were set in various ways, and characteristics of a resonator 21 were obtained through simulation calculation. Conditions for the simulation other than the pitch p and the thickness t0 were as follows.

Piezoelectric film:
Material: LiTaO₃
Euler angles: (0°, 16°, 0°)
Thickness: t0

First acoustic film
Material: SiO₂
Thickness (t1): Set in accordance with t0 such that t0:t1=0.40:0.20

Second acoustic film
Material: HfO₂
Thickness (t2): Set in accordance with t0 such that t0:t2=0.40:0.16

FIG. 12 is a contour map illustrating a result of calculation of a maximum value θmax of the impedance phase. In the figure, a line L21 and a line L22 are straight lines indicating a range within the maximum value θmax is approximately 82° or larger.

It can be seen by focusing upon the same value of pitch in FIG. 12 that there is a range of values of the thickness t0 with which the maximum value θmax becomes larger than or equal to a certain value (e.g., 82 ° or larger). For example, it can be seen that a variation of about ±5% can be tolerated.

### (Thicknesses of Acoustic Films)

Next, a ratio of the thickness t1 of the first acoustic film 59A and the thickness t2 of the second acoustic film 59B to the thickness t0 of the piezoelectric film 7 in the above simulation was selected such that the maximum value θmax of the impedance phase becomes large. More specifically, the ratio was selected as follows.

The characteristics of the resonator 21 were obtained through simulation calculation by performing simulation calculation while setting various values for the thickness t1 and the thickness t2 and keeping the thickness t0 constant. Conditions for this simulation were substantially the same as those for the simulation illustrated in FIG. 12. Conditions different from those for the simulation illustrated in FIG. 12 were as follows.

Thickness t0 of the piezoelectric film: 0.40 μm

Thickness t1 of the first layer: 0.16 μm to 0.24 μm

Thickness t2 of the second layer: 0.06 μm to 0.28 μm

FIG. 13 is a diagram illustrating the maximum value θmax of the impedance phase calculated in the simulation.

As illustrated in the figure, the maximum value θmax is large when t1=0.20 μm and t2=0.16 μm. A ratio of the thicknesses t0 to t2 at this time is as follows as described in the conditions for the simulation illustrated in FIG. 12.

t0:t1:t2=0.40:0.20:0.16

It can be seen from FIG. 13 that even if the thickness t1 and/or the thickness t2 is different, by about 0.02 μm, from a value with which the above ratio is achieved, a large value can be obtained as the maximum value θmax. 0.02 μm is 5% of the thickness t0 (0.40 μm). It can be seen, therefore, that the thickness t1 and the thickness t2 may be within a range of ±5% from the above ratio, as in the first example.

With respect to the thickness of each film, the thickness of the piezoelectric film may be from 97% to 103% and the thickness of each of the plurality of the acoustic films may be from 95% to 105% of values at a time when the ratios of the thicknesses of the films are the same. With these values, the frequency characteristic can be stably achieved.

In the illustrated example, a thickness from an upper surface of the support substrate 53 to the upper surface of the piezoelectric film 57 in the chip 7A is smaller than a thickness from the upper surface of the support substrate 53 to the upper surface of the piezoelectric film 57 in the chip 7B. The chip 7A and the chip 7B, therefore, are different from each other in terms of the total thickness of the plurality of acoustic films 59 and the piezoelectric film 57.

A ratio of the thickness of the conductive layer 35 (the excitation electrodes 37 and the reflectors 39) to the thickness of the multilayer film 55 and the piezoelectric film 57 may be the same (as in the illustrated example) or different between the chip 7A and the chip 7B. Similarly, a ratio of the thickness of the support substrate 53 to the thickness of the multilayer film 55 and the piezoelectric film 57 may be the same (as in the illustrated example) or different between the chip 7A and the chip 7B. A ratio of the total thickness of the plurality of acoustic films 59 and the piezoelectric film 57 in the chip 7A to the total thickness of the plurality of acoustic films 59 and the piezoelectric film 57 in the chip 7B may be the same as (as in the illustrated example) or different from a ratio of the pitch p in the chip 7A to the pitch p in the chip 7B.

As described above, in the present embodiment, the acoustic wave filter 1 includes a first chip (chip 7A) and a second chip (chip 7B) electrically connected to the chip 7A. Each of the chips includes the support substrate 53, the plurality of acoustic films 59, the piezoelectric film 57, and the excitation electrodes sequentially stacked on one another in this order. The plurality of acoustic films 59 are sequentially stacked on the support substrate 53, and materials for acoustic films stacked on each other are different from each other. The chip 7A and the chip 7B are the same in terms of the total number of layers of the plurality of acoustic films 59 and the piezoelectric film 57, order of arrangement of materials in the stacking direction, and the ratio of the thicknesses of the films. The chip 7A and the chip 7B are different from each other in terms of the total thickness of the plurality of acoustic films 59 and the piezoelectric film 57.

An insertion loss and spurious emission of the filter 1, therefore, can be reduced compared to, for example, when an acoustic wave filter is achieved by a single chip 7. Details, for example, will be described hereinafter.

A frequency difference between the serial resonators 21S and the parallel resonators 21P is usually achieved by making the pitch p of the excitation electrodes 37 different between the serial resonators 21S and the parallel resonators 21P. In the case of a high-frequency device employing the multilayer film 55 and the piezoelectric film 57 like the filter 1, on the other hand, the frequency of resonators 21 hardly increases even if the pitch p is reduced. As a result, it is difficult to secure a frequency difference between the serial resonators 21S and the parallel resonators 21P.

The materials for and the thicknesses of the multilayer film and the piezoelectric film 57 and the like are optimally designed (optimal design values are obtained) on the basis of, for example, simulations and/or experiments such that an insertion loss and spurious emission are reduced. The design values are, for example, highly correlated with the pitch p. When a difference in the pitch p between the serial resonators 21S and the parallel resonators 21P is increased to secure a frequency difference between the two, therefore, an insertion loss and/or spurious emission increases in at least one of the serial resonators 21S and the parallel resonators 21P.

As described in prior application 1, the resonant frequency increases as the piezoelectric film 57 and/or the multilayer film 55 becomes thinner. In the present embodiment, on the other hand, the thickness of the films in the chip 7A is smaller than that in the chip 7B. The frequency in the chip 7A, therefore, can be made higher than that in the chip 7B more easily. Accordingly, the frequency difference between the serial resonators 21S and the parallel resonators 21P can be secured more easily.

The chip 7A and the chip 7B are the same in terms of the number of layers of the piezoelectric film 57 and the multilayer film 55, order of stacking of the materials, and the ratio of the thicknesses of the films. In each of the chips 7, for example, therefore, the configuration of the piezoelectric film 57 and the multilayer film 55 close to an optimal design can be employed in relation to the pitch p. As a result, an insertion loss and/or spurious emission can be reduced in the filter 1 as a whole.

As understood from the above description, the total thickness of the piezoelectric film 57 and the multilayer film 55 is basically reduced in a chip 7 (7A here) whose pitch p is relatively small. As mentioned earlier, however, the ratio of the pitch p between the chips 7A and 7B and the ratio of the total thickness of the piezoelectric film 57 and the multilayer film 55 between the chip 7A and the chip 7B are not necessarily the same. When optimal values are comprehensively calculated for various parameters in designing of each of the chips 7, for example, the ratio of the total thickness of the multilayer film 55 and the piezoelectric film 57 in relation to the pitch p might be different between the two chips 7. In addition, depending on magnitude of the frequency difference between the two chips 7 (not necessarily 7S and 7P) and/or the thicknesses of the various layers, the pitch p in the chip 7A and the pitch p in the chip 7B can be the same.

In addition, the present embodiment, the filter 1 may include a band-pass filter. More specifically, the chip 7A may include the plurality of serial resonators 21S (may be the chip 7S). The chip 7B may include the plurality of parallel resonators 21P (may be the chip 7P). The resonant frequency of the plurality of serial resonators 21S may be made higher than that of the plurality of parallel resonators 21P. The plurality of serial resonators 21S and the plurality of parallel resonators 21P may be electrically connected to each other to form a ladder band-pass filter. The total thickness of the plurality of acoustic films 59 and the piezoelectric film 57 in the chip 7A may be made smaller than that of the plurality of acoustic films 59 and the piezoelectric film 57 in the chip 7B.

In this case, for example, a band-pass filter having a passband in a relatively high frequency band (e.g., 5 GHz) can be achieved. With this band-pass filter, an insertion loss and spurious emission can be reduced.

In addition, in the present embodiment, the filter 1 may include a band-elimination filter. More specifically, the chip 7A may include the plurality of parallel resonators 21P (may be the chip 7P). The chip 7B may include the plurality of serial resonators 21S (may be the chip 7S). The resonant frequency of the plurality of serial resonators 21S may be made lower than that of the plurality of parallel resonators 21P. The plurality of serial resonators 21S and the plurality of parallel resonators 21P may be electrically connected to each other to form a ladder band-pass filter. The total thickness of the plurality of acoustic films 59 and the piezoelectric film 57 in the chip 7A may be made smaller than that of the plurality of acoustic films 59 and the piezoelectric film 57 in the chip 7B.

In this case, for example, a band-elimination filter having a passband in a relatively high frequency band (e.g., 5 GHz) can be achieved. With this band-elimination filter, an insertion loss and spurious emission can be reduced.

The above description of the band-pass filter and the band-elimination filter can be summarized as follows. In the present embodiment, each of the chips 7A and 7B may include the resonators 21. The resonant frequency of the resonators 21 in the chip 7A may be made higher than that of the resonators 21 in the chip 7B. The total thickness of the plurality of acoustic films 59 and the piezoelectric film 57 in the chip 7A may be made smaller than that of the plurality of acoustic films 59 and the piezoelectric film 57 in the chip 7B.

In addition, in the present embodiment, for example, the support substrate 53 of the chip 7A is thinner than the support substrate 53 of the chip 7B.

The support substrate 53 affects, for example, temperature characteristics of the excitation electrodes 37 (resonators 21) with thermal stresses caused between the support substrate 53 and the multilayer film 55 (piezoelectric film 57). When the support substrate 53 is relatively thin in the chip 7A whose multilayer film 55 and piezoelectric film 57 are relatively thin, therefore, thermal characteristics can be made the same between the two chips 7 more easily. In other words, the thermal characteristics can be improved in both the two chips more easily.

In addition, in the present embodiment, the filter 1 further includes the mounting board 5 and the sealing part 9. The mounting board 5 includes a first surface (the upper surface of the mounting board 5) on which the chips 7A and 7B are mounted. The sealing part 9 covers the upper surface of the mounting board 5 from above the chips 7A and 7B. The height h1 from the upper surface of the mounting board 5 to the surface of the chip 7A opposite from the mounting board 5 is smaller than the height h2 from the upper surface of the mounting board 5 to the surface of the chip 7B opposite from the mounting board 5. The height from the upper surface of the mounting board 5 to the surface of the sealing part 9 opposite from the mounting board 5 is the same between the position of the chip 7A and the position of the chip 7B.

In this case, for example, the amount of change in the frequency of the chip 7A when the temperature of the filter 1 increases is smaller than when the height h1 and the height h2 are the same (this case is included in the techniques of the present disclosure). That is, the thermal characteristics of the chip 7A improve. The thermal characteristics of the chip 7B, on the other hand, deteriorate compared to when the height h1 and the height h2 are the same. This has been confirmed by an experiment conducted by the inventor and his colleagues. A reason why such effects occur is that when the height h1 is small, for example, the sealing part 9 above the chip 7A is thick, and an effect of suppressing warping of the chip 7A improves. Another reason is that when the height h1 is small, for example, a part of the sealing part 9 located above the chip 7A is located to a side of the chip 7B and applies stress to the side of the chip 7B, thereby promoting warping of the chip 7B. When such effects of the sealing part 9 are ignored, the thermal characteristics of the chip 7A whose frequency is relatively high tend to deteriorate compared to those of the chip 7B. By giving priority to the thermal characteristics of the chip 7A over those of the chip 7B in improvement in consideration of the effects of the sealing part 9, therefore, thermal characteristics can be improved in the filter 1 as a whole.

In addition, although the support substrate 53 and the multilayer film 55 are directly connected with each other, an additional layer may be included in-between. The additional layer may be an adhesion layer or an insulating layer, or may be a laminated film composed of the same materials as the multilayer film. Such an additional layer may be provided for both the chip 7A and the chip 7B or one of the chips 7A and 7B.

In addition, although the configuration with which a frequency difference is achieved and spurious emission is suppressed by making the ratios of the thicknesses of the acoustic films and the piezoelectric film the same and the total thicknesses different between the chip 7A and the chip 7B has been described as an example in the present embodiment, it is needless to say that the thicknesses of the layers need not be different. When a chip is divided in a filter, a layout of resonators can be adjusted as described above, and, for example, power resistance of only resonators that need power resistance may be increased by using different electrode materials or layer configurations of electrodes for the two chips. In addition, different methods for mounting a chip on the mounting board may be used for the two chips. That is, one of the chips may be a so-called wafer level package, and the other chip may be mounted as illustrated in FIG. 2. Because, in general, Cu wires or the like can be accurately patterned in a wafer level package composed of a resin, only resonators whose inductors or capacitors need to be fabricated accurately may be created in chips subjected to wafer level packaging.

### <Examples of Use of Acoustic Wave Filter>

Some examples of various electronic parts and electronic devices including the above-described filter 1 will be described hereinafter.

### (Splitter)

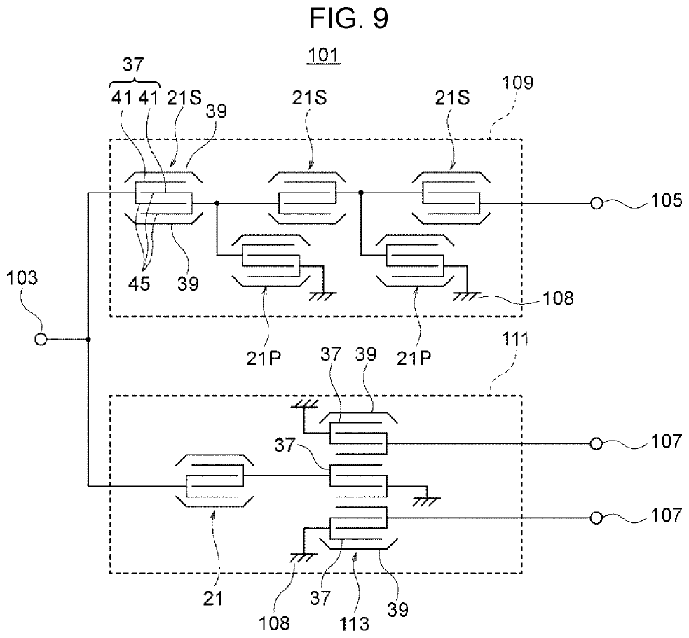

FIG. 9 is a circuit diagram schematically illustrating the configuration of a splitter 101 as an example of use of the filter 1. As understood from reference numerals shown in an upper-left part of a page of the figure, the figure schematically illustrates the interdigital electrodes 41 as bifurcated forks and the reflectors 39 as lines with both ends bent.

More specifically, the illustrated splitter 101 is configured as a duplexer. The splitter 101 includes, for example, a transmission filter 109 that filters a transmission signal from a transmission terminal 105 and that outputs the filtered transmission signal to an antenna terminal 103 and a reception filter 111 that filters a reception signal from the antenna terminal 103 and that outputs the filtered reception signal to a pair of reception terminals 107.

In the illustrated example, the filter 1 as a band-pass filter is used as the transmission filter 109. Although not particularly illustrated, the filter 1 as a band-pass filter may be used as the reception filter 111 instead of, or in addition to, the transmission filter 109.

The splitter 101 may be achieved, for example, by mounting a chip (the chip 7 here) that achieves the transmission filter 109 and a chip that achieves the reception filter 111 on the same mounting board 5. In this case, a part of the filter 1 (the transmission filter 109 here) and a part or the entirety of the other filter (the reception filter 111 here) may be provided on the same chip. Alternatively, for example, the transmission filter 109 and the reception filter 111 may each include a mounting board 5 and a chip (may be separately packaged) and mounted on the same circuit board, which is not illustrated.

As understood from the above description, the antenna terminal 103, the transmission terminal 105, and/or the reception terminals 107 may be regarded as chip terminals 29 (FIG. 6), external terminals 3 (FIGS. 1 to 3), or terminals provided on the circuit board, which is not illustrated, on which the filter 1 is mounted. When reference potential parts 108 are terminals, the same holds for the terminals. In the illustrated example, for example, the transmission terminal 105 may be regarded as the input chip terminal 29A or the input external terminal 3A (for the filter 1 as the transmission filter 109). The antenna terminal 103 may be regarded as the output chip terminal 29B or the output external terminal 3B. The reference potential parts 108 may be regarded as the reference potential chip terminals 29G or the reference potential external terminals 3G.

As described above, in the illustrated example, the transmission filter 109 is achieved by the filter 1. The configuration of the filter 1 is as described above. As described above, the number of serial resonators 21S and parallel resonators 21P may be appropriately determined, and FIG. 9 illustrates a different number of serial resonators 21S and parallel resonators 21P from in FIGS. 3 and 6.

The reception filter 111 includes a resonator 21 and a multimode filter (includes a double-mode filter) 113 in the illustrated example. The multimode filter 113 includes a plurality of (three in the illustrated example) excitation electrodes 37 arranged in a propagation direction of acoustic waves and a pair of reflectors 39 arranged on both sides of the excitation electrodes 37.

### (Communication Apparatus)

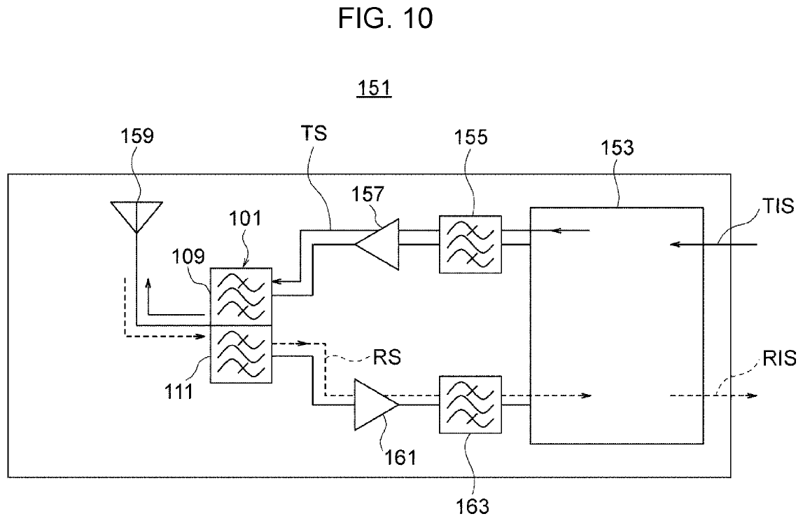

FIG. 10 is a block diagram illustrating a main part of a communication apparatus 151 as another example of use of the filter 1. The communication apparatus 151 performs wireless communication employing radio waves and includes, for example, the splitter 101.

In the communication apparatus 151, a transmission information signal TIS including information to be transmitted is subjected to modulation and frequency raising (conversion into a high-frequency signal having a carrier wave frequency) in a radio frequency integrated circuit (RF-IC) 153 and converted into a transmission signal TS. A band-pass filter 155 removes unnecessary components of the transmission signal TS outside a transmission passband, and an amplifier 157 amplifies the transmission signal TS. The transmission signal TS is then input to the splitter 101 (transmission terminal 105). The splitter 101 (transmission filter 109) then removes unnecessary components of the input transmission signal TS outside the transmission passband and outputs the transmission signal TS subjected to the removal to an antenna 159 from the antenna terminal 103. The antenna 159 converts the input electrical signal (transmission signal TS) into a wireless signal (radio wave) and transmits the wireless signal.

In addition, in the communication apparatus 151, a wireless signal (radio wave) received by the antenna 159 is converted by the antenna 159 into an electrical signal (reception signal RS) and input to the splitter 101 (antenna terminal 103). The splitter 101 (reception filter 111) removes unnecessary components of the input reception signal RS outside a reception passband and outputs the reception signal RS to an amplifier 161 from a reception terminal 107. The amplifier 161 amplifies the output reception signal RS, and a band-pass filter 163 removes unnecessary components outside the reception passband. The reception signal RS is then subjected to frequency reduction and demodulation and converted into a reception information signal RIS by the RF-IC 153.

The transmission information signal TIS and the reception information signal RIS may be low-frequency signals (baseband signals) including appropriate information and are, for example, analog audio signals or digitized signals. A passband for wireless signals may be appropriately set, and in the present embodiment, can be a relatively high-frequency passband (e.g., 5 GHz or higher). A modulation method may be phase modulation, amplitude modulation, frequency modulation, or any selective combination of two or more of these. Although FIG. 10 illustrates a direct-conversion system as a circuit system, another appropriate system, such as a double-superheterodyne system, may be employed, instead. In addition, since FIG. 10 schematically illustrates only the main part, a low-pass filter, an isolator, or the like may be added at an appropriate position, or a position of the amplifier or the like may be changed.

### (Composite Filter)

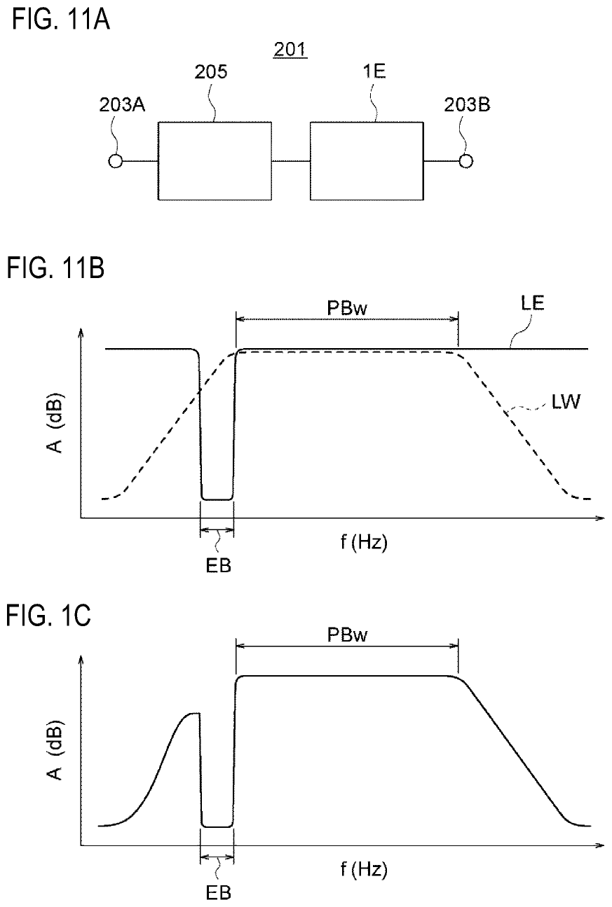

FIG. 11A is a block diagram schematically illustrating the configuration of a composite filter 201 as another example of use of the filter 1.

The composite filter 201 is configured, for example, as a band-pass filter that outputs a signal input to an input terminal 203A within a certain passband from an output terminal 203B. The composite filter 201 includes a broadband filter 205 connected in series with the input terminal 203A and the output terminal 203B and the filter 1 (hereinafter referred to as a “filter 1E”) as a band-elimination filter. Order in which the broadband filter 205 and the filter 1E are connected from the input terminal 203A to the output terminal 203B may be reversed from the illustrated example.

The broadband filter 205 may be an acoustic wave filter or a filter that does not employ acoustic waves. The latter may be, for example, a filter that employs a parallel resonance circuit including an inductor (coil) and a capacitor (condenser) or a filter (dielectric filter) that employs a dielectric resonator in which a dielectric is provided between conductors. The filter that employs a parallel resonance circuit may be, for example, a low temperature co-fired ceramics (LTCC) filter, in which conductors that serve as an inductor and a capacitor are provided on a multilayer substrate composed of a ceramic.

As with the various terminals illustrated in FIG. 9, the input terminal 203A and the output terminal 203B may be regarded as chip terminals 29, external terminals 3, or terminals provided on a circuit board, which is not illustrated, on which the broadband filter 205 and the filter 1 are mounted. In other words, the broadband filter 205 and the filter 1E may be, for example, partially provided on the same chip, provided on different chips and packaged together, or separately packaged and mounted on a circuit board, which is not illustrated.

FIG. 11B is a diagram illustrating filter characteristics of the broadband filter 205 and the filter 1E and similar to the lower graphs of FIGS. 4 and 5. A line LW represents a characteristic of the broadband filter 205. A line LE represents a characteristic of the filter 1E.

A passband PBw of the broadband filter 205 is, for example, broader than a stopband EB of the filter 1E. A rate of change (only an absolute value will be focused upon here. The same will hold hereinafter) of attenuation on both sides of the passband PBw of the broadband filter 205 is lower (a slope is gentle) than a rate of change of attenuation on both sides of the stopband EB of the filter 1E. It is generally said that the higher the rate of change, the better the characteristic of the filter. The stopband EB is adjacent to a low-frequency side of the passband PBw.

FIG. 11C is a diagram illustrating a filter characteristic of the composite filter 201 and similar to FIG. 11B.

As illustrated in the figure, the filter characteristic of the composite filter 201 is the same as that of the broadband filter 205 except that a rate of change of attenuation is higher on the low-frequency side of the passband PBw. The rate of change is substantially the same as the rate of change on a high-frequency side of the stopband EB of the filter 1E. A filter characteristic whose passband is relatively broad and whose rate of change of attenuation at an end of the passband is high can thus be achieved, for example, by combining the filter 1E with another filter.

Although the filter 1E having the stopband EB adjacent to the low-frequency side of the passband PBw is provided in the illustrated example, a filter 1E having a stopband EB adjacent to the high-frequency side of the passband PBw may be provided instead of, or in addition to, the above filter 1E. The passband PBw and the stopband EB may have the same frequency at respective ends thereof, may be separate from each other, or may overlap each other. A frequency difference at the ends (a degree of adjacency) may be appropriately determined. The composite filter 201 may be used, for example, as the transmission filter 109 and/or the reception filter 111 of the splitter 101 or the band-pass filter 155 and/or 163 of the communication apparatus 151.

The techniques of the present disclosure are not limited to the above embodiment and may be implemented in various modes.

When a filter is a ladder resonator filter, a plurality of resonators distributed between two or more chips are not limited to serial resonators and parallel resonators. For example, the plurality of serial resonators basically have the same resonant frequency. Resonant frequencies of serial resonators, however, are sometimes adjusted to be different from one another in order to improve a filter characteristic. In such a case, the plurality of serial resonators whose resonant frequencies are different from one another may be distributed between a plurality of chips whose absolute values of thicknesses of films are different from one another. The same holds for the plurality of parallel resonators.

The filter including a plurality of chips whose absolute values of thicknesses of films are different from one another is not limited to a ladder resonator filter. For example, FIG. 9 illustrates the reception filter 111 including the resonator 21 and the multimode filter 113. The resonator 21 and the multimode filter 113 may be distributed between two chips, instead. In addition, for example, the filter may be the ladder resonator filter illustrated in FIG. 3 whose parallel resonators are replaced by inductors, instead. The plurality of serial resonators may be distributed between a plurality of chips whose absolute values of thicknesses of films are different from one another.

A package of a filter may have one of various configurations other than the configurations described in the embodiment. For example, each chip may have a configuration in which a box-shaped cover is put on the fixed substrate 27 in such a way as to cover the excitation electrodes 37 (a so-called wafer level package acoustic wave chip). The chip may then be mounted with a top surface of the cover facing the mounting board 5.

In the embodiment, the support substrate 53, the multilayer film 55, and the piezoelectric film 57 are illustrated as having similar areas. The support substrate 53, the multilayer film 55, and the piezoelectric film 57, however, may have different areas, instead. For example, the area of the piezoelectric film 57 may be made smaller than that of the multilayer film 55, and a part of an upper surface of the multilayer film 55 may be exposed. Alternatively, for example, the multilayer film 55 (and the piezoelectric film 57) may be made smaller than the support substrate 53, and a part of the upper surface of the support substrate 53 may be exposed. In such a case, the chip terminals 29 may be located not on the piezoelectric film 57 but on the upper surface of the multilayer film 55 or the support substrate 53, instead.

The splitter including a plurality of filters is not limited to a duplexer. For example, the splitter (multiplexer) may be a triplexer including three filters or a quadplexer including four filters. Depending on a technical field, a term multiplexer can be used in a narrow sense. The term multiplexer can be used, for example, as a term referring to only a device that outputs two or more signals while mixing the signals with each other. In the present disclosure, the term multiplexer is used in a broad sense, and the multiplexer need not have a function of, for example, mixing signals with each other.

### REFERENCE SIGNS LIST

1 acoustic wave filter, 7A first chip, 7B second chip, 37 excitation electrode, 53 support substrate, 57 piezoelectric film, 59 acoustic film.

1. An acoustic wave filter comprising:
a first chip; and
a second chip electrically connected to the first chip,
wherein each of the first chip and the second chip includes
a support substrate,
a plurality of acoustic films that are sequentially stacked on the support substrate and whose materials are different between acoustic films stacked on each other,
a piezoelectric film located on the plurality of acoustic films, and
an excitation electrode located on the piezoelectric film.

2. The acoustic wave filter according to claim 1,
wherein at least one of the first chip or the second chip includes a plurality of serial resonators, each of which includes the excitation electrode, and
wherein the plurality of serial resonators are electrically connected in series with one another and sequentially arranged in one direction.

3. The acoustic wave filter according to claim 1,
wherein the first chip and the second chip are same in terms of a total number of layers of the plurality of acoustic films and the piezoelectric film and order of arrangement of materials for the plurality of acoustic films and the piezoelectric film in a stacking direction and a difference between ratios of thicknesses of the films in the first chip and the second chip is 5% or lower, and
wherein the first chip and the second chip are different from each other in terms of a total thickness of the plurality of acoustic films and the piezoelectric film.

4. The acoustic wave filter according to claim 3,
wherein the first chip includes a plurality of serial resonators, each of which includes the excitation electrode,
wherein the second chip includes a plurality of parallel resonators, each of which includes the excitation electrode,
wherein a resonant frequency of the plurality of serial resonators is higher than a resonant frequency of the plurality of parallel resonators,
wherein the plurality of serial resonators and the plurality of parallel resonators are electrically connected to each other and form a ladder band-pass filter, and
wherein the total thickness of the plurality of acoustic films and the piezoelectric film in the first chip is smaller than the total thickness of the plurality of acoustic films and the piezoelectric film in the second chip.

5. The acoustic wave filter according to claim 3,
wherein the first chip includes a plurality of parallel resonators, each of which includes the excitation electrode,
wherein the second chip includes a plurality of serial resonators, each of which includes the excitation electrode,
wherein a resonant frequency of the plurality of serial resonators is lower than a resonant frequency of the plurality of parallel resonators,
wherein the plurality of serial resonators and the plurality of parallel resonators are electrically connected to each other and form a ladder band-elimination filter, and
wherein the total thickness of the plurality of acoustic films and the piezoelectric film in the first chip is smaller than the total thickness of the plurality of acoustic films and the piezoelectric film in the second chip.

6. The acoustic wave filter according to claim 3,
wherein each of the first chip and the second chip includes a resonator including the excitation electrode,
wherein a resonant frequency of the resonator in the first chip is higher than a resonant frequency of the resonator in the second chip, and
wherein the total thickness of the plurality of acoustic films and the piezoelectric film in the first chip is smaller than the total thickness of the plurality of acoustic films and the piezoelectric film in the second chip.

7. The acoustic wave filter according to claim 6,
wherein a thickness of the support substrate of the first chip is smaller than a thickness of the support substrate of the second chip.

8. The acoustic wave filter according to claim 7, further comprising:
a mounting board including a first surface on which the first chip and the second chip are mounted; and
a sealing part that covers the first surface from above the first chip and the second chip,
wherein a height from the first surface to a surface of the first chip opposite from the first surface is smaller than a height from the first surface to a surface of the second chip opposite from the first surface, and
wherein a height from the first surface to a surface of the sealing part opposite from the first surface is same between a position of the first chip and a position of the second chip.

9. The acoustic wave filter according to claim 1,
wherein at least one of the first chip and the second chip includes an additional layer between the support substrate and the acoustic films.

10. A communication apparatus comprising:
the acoustic wave filter according to claim 1;
an antenna electrically connected to the acoustic wave filter; and
an integrated circuit device electrically connected to the antenna through the acoustic wave filter.
